(19) United States
(12) Patent Application Publication
(10) Pub. No.: US 2026/0311966 A1
(43) Pub. Date: Oct. 8, 2026

(54) WAVE-ASSISTED HYBRID PLASMA SOURCE

(71) Applicant: Tokyo Electron Limited, Tokyo (JP)

(72) Inventors: Qiang Wang, Austin, TX (US); Shyam Sridhar, Austin, TX (US); Peter Lowell George Ventzek, Austin, TX (US); Mitsunori Ohata, Taiwa-cho (JP)

(21) Appl. No.: 19/169,621

(22) Filed: Apr. 3, 2025

(51) Int. Cl. H01J 37/32

(52) U.S. Cl. CPC H01J 37/32155; H01J 37/32119; H01J 37/32972; H01J 37/3299; H01J 2237/24514; H01J 2237/24564

(57) ABSTRACT

A plasma processing apparatus includes a processing chamber including a dielectric window, a source coil disposed outside the processing chamber at the dielectric window, a secondary coil configured to receive lower frequency RF power coupled to the second coil at a secondary frequency, and one or more magnets configured to generate a direct current magnetic field in the plasma. The source coil is configured to generate plasma in the processing chamber using radio frequency source power coupled to the source coil at a source frequency. The secondary frequency is less than the source frequency.

### TECHNICAL FIELD

The present invention relates generally to plasma processing, and, in particular embodiments, to plasma sources and operating methods thereof.

### SUMMARY

In accordance with an embodiment of the invention, a plasma processing apparatus includes a processing chamber including a dielectric window, a source coil disposed outside the processing chamber at the dielectric window, a secondary coil configured to receive lower frequency RF power coupled to the second coil at a secondary frequency, and one or more magnets configured to generate a direct current magnetic field in the plasma. The source coil is configured to generate plasma in the processing chamber using radio frequency source power coupled to the source coil at a source frequency. The secondary frequency is less than the source frequency.

In accordance with another embodiment of the invention, a plasma processing system includes a processing chamber including a dielectric window, a source power supply configured to generate radio frequency source power at a source frequency, a source coil electrically coupled to the source power supply and disposed outside the processing chamber at the dielectric window, a secondary power supply configured to generate lower frequency RF power at a secondary frequency, a secondary coil electrically coupled to the secondary power supply and configured to receive the lower frequency RF power, and one or more magnets configured to generate a direct current magnetic field in the plasma. The source coil is configured to generate plasma in the processing chamber using the RF source power. The secondary frequency is less than the source frequency.

In accordance with still another embodiment of the invention, a method for plasma processing of a substrate includes generating plasma in a processing chamber by applying radio frequency source power at a source frequency to a source coil, generating a direct current magnetic field in the processing chamber, and applying lower frequency radio frequency power to a secondary coil at a secondary frequency less than the source frequency. While applying the lower frequency radio frequency power and generating the magnetic field and the plasma, plasma characterization information of the plasma is obtained and the secondary frequency is adjusted according to the plasma characterization information. The method further includes processing the substrate using the plasma.

### BACKGROUND

Plasma processing systems are widely used in semiconductor manufacturing for various applications including etching, deposition, and surface modification. These systems typically employ radio frequency (RF) power to generate and sustain plasma within a processing chamber. In semiconductor manufacturing processes, achieving uniform plasma characteristics at the substrate level is crucial for ensuring consistent processing results across the entire substrate (e.g., wafer) surface. The uniformity of plasma density, ion flux, and radical distribution directly impacts critical process parameters such as etch rate, deposition rate, and feature profile control.

The semiconductor industry continually demands more precise control over plasma characteristics to meet the requirements of increasingly complex device structures. As feature sizes shrink and aspect ratios increase, the need for enhanced plasma uniformity control becomes more critical, especially for advanced etch and deposition processes that require precise manipulation of plasma density and ion energy distribution at the substrate level.

Plasma sources can be categorized based on coupling mechanisms. Some examples include inductively coupled plasma (ICP) sources, capacitively coupled plasma (CCP) sources, and wave plasma sources, such as a surface-wave plasma (SWP) source and a helicon plasma source (HPS). ICP sources are valued for their ability to generate high-density plasmas with good uniformity, while wave plasma sources can achieve extended power deposition through the propagation of electromagnetic waves within the plasma. Both ICP sources and wave plasma sources offer distinct advantages for specific applications, but also come with inherent limitations that affect process control and efficiency.

### BRIEF DESCRIPTION OF THE DRAWINGS

For a more complete understanding of the present invention, and the advantages thereof, reference is now made to the following descriptions taken in conjunction with the accompanying drawings, in which:

FIG. 1 illustrates a schematic diagram of a plasma processing system that includes an example plasma processing apparatus with a source coil configured to generate plasma, a secondary coil configured to propagate an electromagnetic wave in the plasma, and a magnet configured to generate a DC magnetic field in the plasma in accordance with embodiments of the invention;

FIG. 2 illustrates a schematic diagram of another example plasma processing apparatus where the magnet is disposed above the source coil (also referred to as the first coil) and the secondary coil in accordance with embodiments of the invention;

FIG. 3 illustrates a schematic diagram and associated qualitative power deposition of still another example plasma processing apparatus where the secondary coil is the inner coil and the magnet is disposed above the source coil and the secondary coil in accordance with embodiments of the invention;

FIG. 4 illustrates a schematic diagram and associated qualitative power deposition of a conventional ICP plasma reactor for comparison purposes;

FIGS. 5A and 5B illustrate a qualitative comparison of power deposition of plasma processing apparatuses describe herein as the secondary frequency is varied where FIG. 5A shows power deposition with a 10 MHz secondary frequency and FIG. 5B shows power deposition with a 2 MHz secondary frequency in accordance with embodiments of the invention;

FIGS. 6A and 6B illustrate a qualitative comparison of power deposition of plasma processing apparatuses described here as the applied power is varied where FIG. 6A shows power deposition with 500 W applied source power and 1 kW applied secondary power, and

FIG. 6B shows power deposition with 250 W applied source and 250 W secondary power in accordance with embodiments of the invention; and

FIG. 7 illustrates an example method for plasma processing of a substrate in accordance with embodiments of the invention.

Corresponding numerals and symbols in the different figures generally refer to corresponding parts unless otherwise indicated. The figures are drawn to clearly illustrate the relevant aspects of the embodiments and are not necessarily drawn to scale. The edges of features drawn in the figures do not necessarily indicate the termination of the extent of the feature.

### DETAILED DESCRIPTION OF ILLUSTRATIVE EMBODIMENTS

The making and using of various embodiments are discussed in detail below. It should be appreciated, however, that the various embodiments described herein are applicable in a wide variety of specific contexts. The specific embodiments discussed are merely illustrative of specific ways to make and use various embodiments, and should not be construed in a limited scope.

In conventional inductively coupled plasma (ICP) sources, radio frequency (RF) power is primarily deposited near the source (e.g., within a thin layer near the top window of the processing chamber). This creates a substantial physical gap between the power deposition zone and the substrate being processed. The large separation between the power deposition zone reduces the amount of power reaching the substrate. One potential drawback of the power being so attenuated at the substrate is undesirably weak control of plasma uniformity at the substrate level (e.g., near wafer edge regions).

Various approaches can be taken to extend power deposition deeper into the plasma chamber. Adding external magnets is one possible modification to conventional ICP sources that may be made to extend power deposition within the plasma (i.e., toward the processing surface of the substrate). However, in order to achieve meaningful power deposition improvement, high magnetic field strengths inside the chamber are required (such as for a typical ICP plasma source operated at 13.6 MHz or 27MHz), which can cause adverse operational issues like plasma instability, nonuniformity across the substrate (e.g., wafer), and overheating of the magnet coils.

In accordance with embodiments herein described, the invention proposes a wave-assisted hybrid high-density plasma source combines the advantages of ICP technology with wave plasma techniques to achieve extended power deposition throughout a processing chamber. Specifically, the proposed hybrid wave-assisted plasma source incorporates both a primary coil (a source coil) operating at a higher frequency (e.g., greater than about 10 MHz) and a secondary coil operating at a lower frequency (e.g., <10 MHz) together with a magnet (or several magnets) generating a relatively weak (e.g., <10 G) external magnetic field in the plasma. This combination of lower frequency RF power combined with a relatively weak direct current (DC) magnetic field can enable electromagnetic wave propagation in the plasma and achieve extended power deposition throughout the processing chamber, such as down to the substrate surface (e.g., wafer level) while maintaining high plasma density and uniformity.

The proposed plasma source is “hybrid” in the sense that while the plasma is generated using an ICP source (generating a high-density plasma, which may be desirable in many applications), a secondary coil and a magnet (or several magnets) are also used to promote electromagnetic waves propagation in the plasma: a unique ICP and wave plasma discharge mode. Since the induced electromagnetic wave propagation by the secondary coil and the magnets is utilized as an effect to extend power deposition within an inductively-coupled plasma generated by the first coil, the proposed plasma source may also be referred to as “wave-assisted.”

In various embodiments, a plasma processing apparatus includes a processing chamber (e.g., a plasma reactor) that has a dielectric window. A substrate holder is disposed in the processing chamber. A source coil (e.g., an RF coil, such as an ICP coil) is disposed outside the processing chamber at the dielectric window. The source coil is coupled to source power (e.g., alternating current (AC) power, such as RF power) of a certain frequency (i.e., a source frequency, such as greater than about 10 MHz). For example, the source coil may be configured to generate plasma in the processing chamber using the source power.

The plasma processing apparatus also includes a magnet (or several magnets) and a secondary coil coupled to power (e.g., AC power, such as RF power) of a lower frequency (i.e., a secondary frequency lower than the source frequency, such less than about 10 MHz, for example). The secondary coil may be configured to propagate electromagnetic waves in the plasma using the lower frequency power and the magnet. The source coil and the secondary coil may have various configurations, including a concentric planar coil configuration (i.e., disposed in substantially the same plane and sharing a common central axis). In one embodiment, the source coil is the inner coil of the concentric planar coils, while the secondary coil is the inner coil in another embodiment.

The magnet (e.g., one or several magnetic coil rings) may be configured to generate a DC magnetic field in the plasma (e.g., less than about 10 G). The magnet may be a permanent magnet, an electromagnet, an electro-permanent magnet (EPM), or a combination thereof. The magnet may also be disposed in a various positions (e.g., relative to the source coil and/or the secondary coil). In the specific example where the source coil and the secondary coil are configured as concentric planar coils, the magnet is disposed within an outer radius of the concentric planar coils in one embodiment. In another embodiment, the magnet is disposed outside an outermost radius of the source coil and the secondary coil.

The source coil may be electrically coupled to a source power supply that is configured to generate the RF source power. Similarly, the secondary coil may be electrically coupled to a secondary power supply that is configured to generate the lower frequency power. A DC power supply may be coupled to the magnet (e.g., when it is implemented as an electromagnet, for example). Some or all of the power supplies may be variable. For example, the secondary frequency of the lower frequency power may be configured to be adjustable based on plasma characterization information (e.g., current-voltage (IV) data, optical emission spectroscopy (OES) data, etc.). For example, one or more sensors may be included to measure the plasma characterization information (e.g., sensor feedback signals).

A controller may also be included that is operationally coupled to one or more controllable components of a plasma processing system, such as a source power supply configured to generate and maintain the plasma, a DC power supply configured to control the strength of the generated DC magnetic field, a secondary power supply configured to enable propagation of electromagnetic waves in the plasma under the generated DC magnetic field, one or more sensors configured to measure plasma characterization information, and others. For example, the controller may include a processor and a non-transitory computer-readable medium (e.g., a memory) storing a program including instructions that, when executed by the processor, perform embodiment methods for plasma processing a substrate disposed in the processing chamber.

The embodiment plasma processing apparatuses, systems, and methods described herein may have the advantage of providing the benefits of both conventional ICP and wave plasma sources while avoiding the operational issues associated with high magnetic field strengths. The embodiments can operate in a hybrid discharge mode where plasma is primarily generated through inductive coupling while electromagnetic wave propagation extends the power deposition zone. The combination of the secondary RF coil and the weak magnetic field can promote wave propagation within the plasma without requiring the high magnetic field strengths that can cause operational issues such as plasma instability and nonuniformity. The embodiments can be implemented with various configurations of the source coil, secondary coil, and magnet placement to accommodate different processing requirements and chamber geometries.

The hybrid approach of the described embodiments may advantageously provide enhanced control of plasma characteristics at the substrate level, particularly near the wafer edge regions where uniformity can be challenging to maintain with conventional ICP sources. Sensors for measuring plasma characterization information can also be included, advantageously enabling optimization of plasma uniformity (such as near the substrate edge) by dynamically adjusting the frequency of the secondary coil based on in situ sensor data (e.g., sensor feedback).

The embodiments described herein also may provide advantages related to field strength and applied power. The embodiments may advantageously operate with lower power requirements than conventional systems while achieving improved process control. For example, the embodiments may be capable of providing improved power deposition while maintaining higher plasma density and uniformity while employing weaker magnetic fields in the plasma (e.g., less than about 10 G, for example). Additionally, the source power may beneficially be kept lower, such as less than about 1 kW.

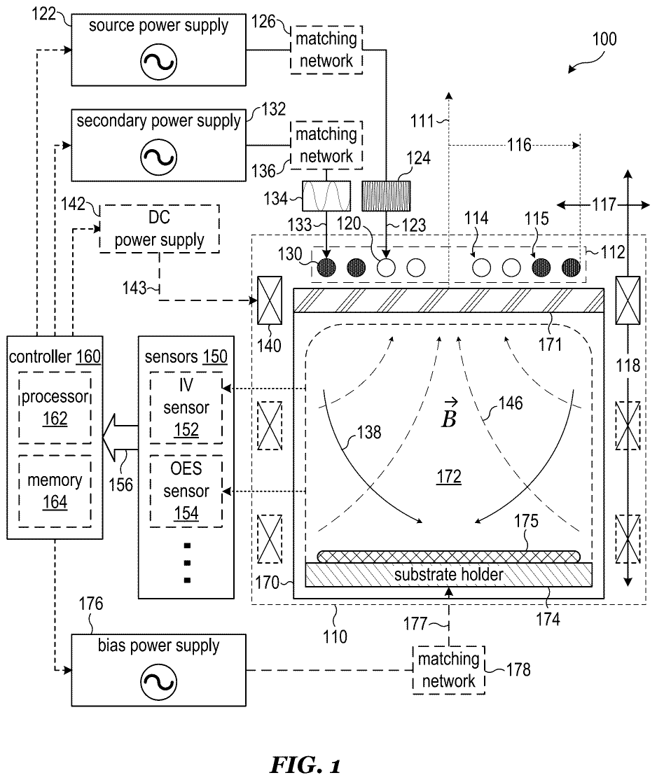

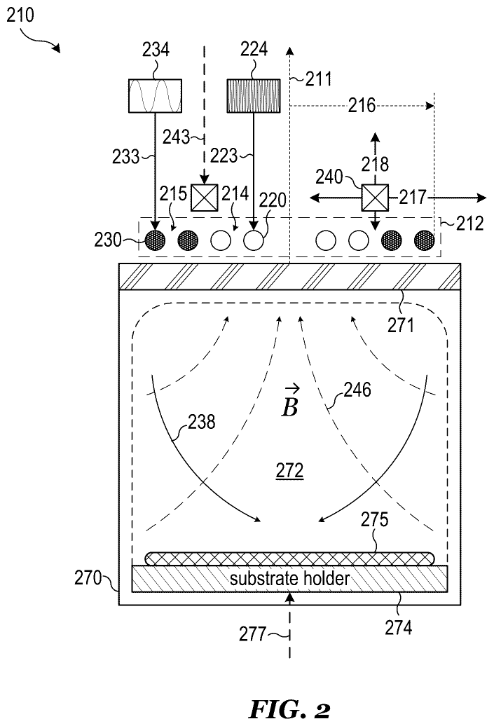

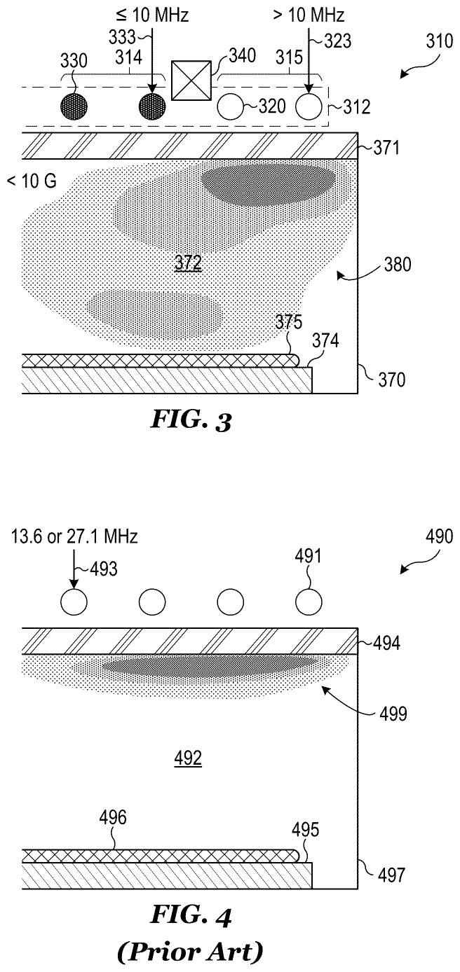

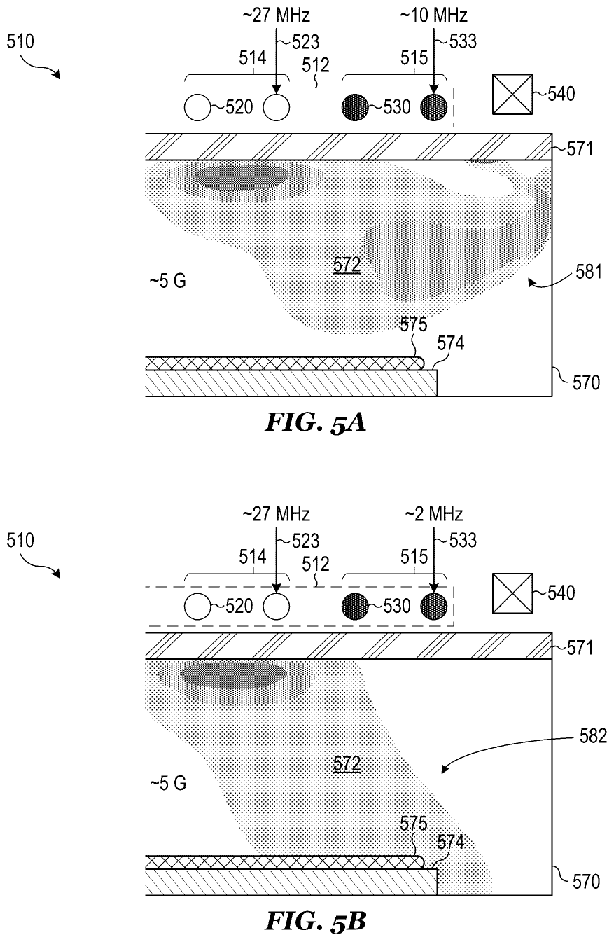

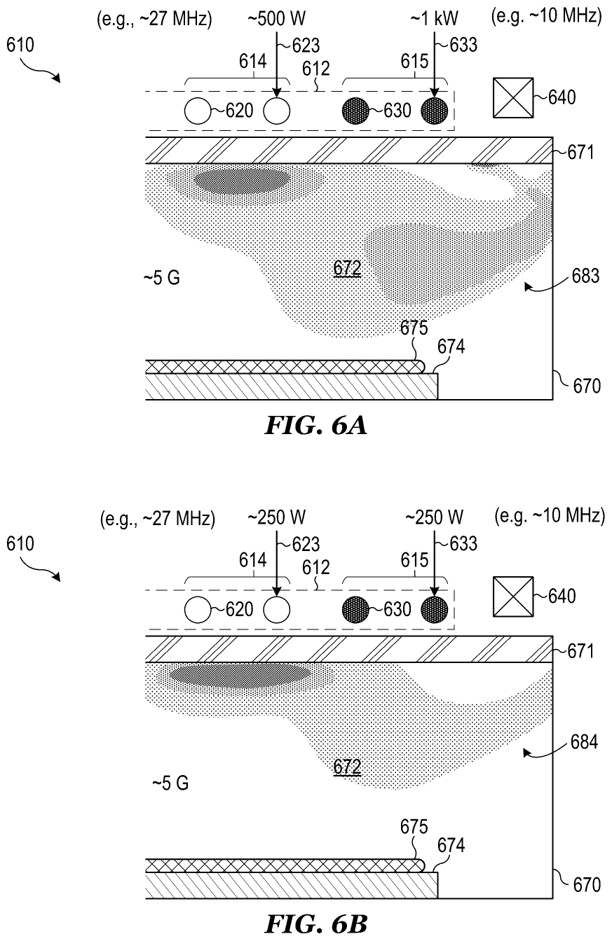

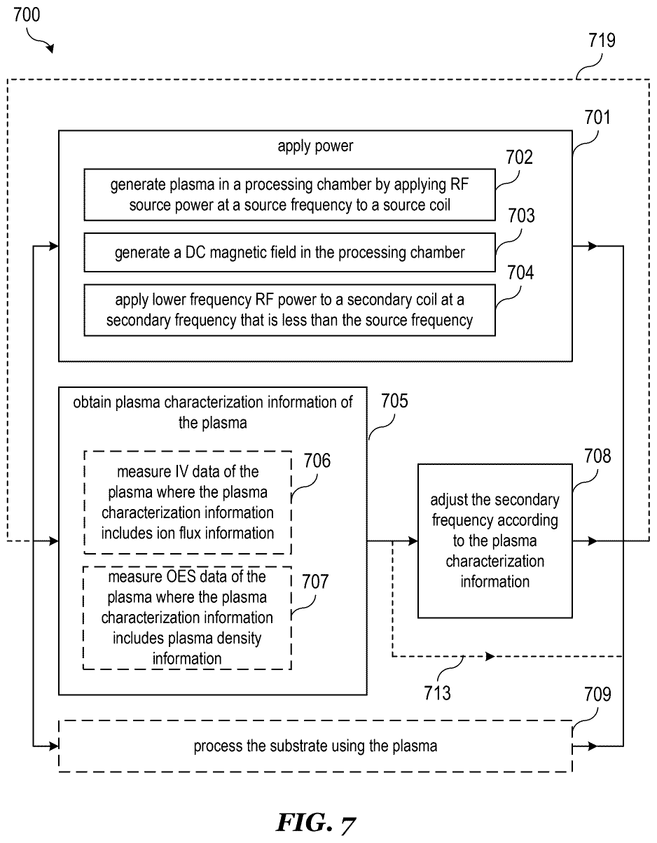

Embodiments provided below describe various plasma processing apparatuses, systems, and methods, and in particular embodiments, plasma processing apparatus, systems and methods that include a magnet and two separate RF coils configured to receive different frequencies. The following description describes the embodiments. FIG. 1 is used to describe a plasma processing system that includes a plasma processing apparatus with a magnet (or several magnets) and two RF coils. Two more example plasma processing apparatuses are described using FIGS. 2 and 3. A conventional ICP plasma reactor is described using FIG. 4 for comparison purposes. Qualitative power depositions are compared using FIGS. 5A-5B and 6A-6B. An example method for plasma processing of a substrate is described using FIG. 7.

FIG. 1 illustrates a schematic diagram of a plasma processing system that includes an example plasma processing apparatus with a source coil configured to generate plasma, a magnet (or several magnets) configured to generate a DC magnetic field in the plasma, and a secondary coil configured to enable electromagnetic wave propagation in the plasma in accordance with embodiments of the invention.

Referring to FIG. 1, a plasma processing system 100 includes a plasma processing apparatus 110 that is configured to generate a plasma 172 in a processing chamber 170. A substrate holder 174 is disposed in the processing chamber 170 and is configured to support a substrate 175. The plasma 172 is generated in the processing chamber using a hybrid approach that involves applying AC power (e.g., RF power) with different frequencies to two separate coils (a source coil 120 and a secondary coil 130) and generating a magnetic field 146 using a magnet 140 (or magnets). The plasma 172 is separated from the source coil 120 and the secondary coil 130 by a dielectric window 171 (i.e., the source coil 120 and the secondary coil 130 are disposed outside the processing chamber 170 at the dielectric window 171).

A source power supply 122 is an AC power supply that is configured to generate source power 123 at a source frequency 124. The source power supply 122 is coupled to the source coil 120, which generates the plasma 172 using the source power 123. In various embodiments, the source power 123 is RF source power (i.e., the source power supply 122 is configured to supply AC power in the RF range). In one embodiment, the source power 123 is continuous wave (CW) RF source power. In another embodiment, the source power 123 is pulsed RF source power. A source power matching network 126 is optionally included between the source power supply 122 and the source coil 120.

The source coil 120 may be any suitable conductor configured as a radiating antenna. In various embodiments, the source frequency 124 is greater than about 10 MHz. In some embodiments, the source frequency 124 is about 13 MHz, such as about 13.6 MHz in one embodiment. In other embodiments, the source frequency 124 is about 27 MHz, and is about 27.1 MHz in one embodiment.

The plasma processing system 100 also includes a secondary power supply 132 (also an AC power supply) that is configured to generate secondary power 133 at a secondary frequency 134. The secondary coil 130 is coupled to the secondary power supply 132 and configured to modulate the plasma 172 using the secondary power 133. In various embodiments, the secondary power 133 is RF power (i.e., the secondary power supply 132 is configured to supply AC power in the RF range). In one embodiment, the secondary power 133 is continuous wave (CW) RF power. In another embodiment, the secondary power 133 is pulsed RF power. A secondary matching network 136 may be optionally included between the secondary power supply 132 and the secondary coil 130.

The secondary frequency 134 is less than the source frequency 124. In various embodiments, the secondary frequency 134 is less than about 10 MHz and is between about 1 MHz and about 10 MHz in some embodiments. In one embodiment, the secondary frequency 134 is about 2 MHz. In another embodiment, the secondary frequency 134 is about 10 MHz. The secondary frequency 134 may be variable and may be adjusted based on real-time measurements of the plasma system (such as IV measurements and/or OES measurements of the plasma).

A bias power supply 176 may also optionally be coupled to the substrate holder 174. The bias power supply 176 may be configured to generate bias power 177, which may be AC power (as shown), DC-biased AC power, DC power, DC bipolar power, or have arbitrary waveforms. A bias matching network 178 may be included between the bias power supply 176 and the substrate holder 174.

The magnet 140 may be any suitable type of magnet, such as a permanent magnet, an electromagnet, an electro-permanent magnet (EPM), or a combination thereof. The magnet 140 may be configured to generate a DC magnetic field in the processing chamber 170. That is, the magnetic field 146 may be substantially unidirectional (as opposed to a bidirectional AC magnetic field, for example). For powered implementations of the magnet 140, a DC power supply 142 may be coupled to the magnet 140 that is configured to generate and provide DC power 143 to the magnet 140 to generate the DC magnetic field.

The strength of the magnetic field 146 may have the advantage of being weaker than magnetic fields generated in related systems. When discussing the strength of the magnetic field 146, it should be understood that the quantity being referred to is the approximate maximum of the magnetic field in the processing chamber 170. For example, the magnetic field 146 may be less than about 10 G throughout the processing chamber 170. In some embodiments, the strength of the magnetic field 146 is between about 1 G and about 10 G. In one embodiment, the strength of the magnetic field 146 is about 5 G. In another embodiment, the strength of the magnetic field 146 is about 2 G. As with the secondary frequency 134, the strength of the magnetic field 146 may also be variable and may be adjusted based on real-time measurements of the plasma system (such as IV measurements and/or OES measurements of the plasma).

The magnetic field 146 may be substantially constant, at least relative to the source frequency 124 and the secondary frequency 134. In various embodiments, the DC power 143 is applied to the magnet 140 as continuous wave DC power to generate a substantially constant magnetic field in the plasma 172. In other embodiments, the DC power 143 is applied as pulsed DC power. The pulsed DC power is applied as a series of square wave pulses in one embodiment. In other embodiments, the pulsed DC power is applied as a series of other waveforms, such as sawtooth, triangle, or arbitrary waveforms as desired.

The combination of the magnetic field 146 with the secondary power 133 applied to the secondary coil 130 may propagate electromagnetic waves 138 in the plasma 172. For example, the plasma 172 could be generated and sustained using only the source coil 120, but the resulting high density plasma would have a power deposition that is concentrated near the dielectric window 171 with substantially no wave propagation within the plasma. When the secondary power 133 is applied to the secondary coil 130 in the presence of the magnetic field 146, the combination may propagate the electromagnetic waves 138 toward the substrate 175 advantageously resulting in extended power deposition. It should be noted that the qualitative arrows of the magnetic field 146 and the electromagnetic waves 138 are intended to provide conceptual guidance and are not necessarily scientifically accurate for the schematic configuration shown.

The source coil 120 and the secondary coil 130 may have any suitable configuration. In various embodiments, the source coil 120 and the secondary coil 130 are arranged as concentric planar coils 112 having a common central axis 111 (as shown). The concentric planar coils 112 have an inner coil 114 (which here is the source coil 120) and an outer coil 115 (the secondary coil 130 in this example). In various embodiments, the identities of the inner coil 114 and the outer coil 115 are switched.

It should be appreciated that the concentric planar coils 112 can be placed directly adjacent to the dielectric window 171 of the processing chamber 170 or can be separated from dielectric window 171 by one or more additional dielectric materials, such as air, Teflon, ceramic, etc. The dielectric window 171 can be selected to minimize reflections of transmitted AC power the RF wave from the processing chamber 170. The concentric planar coils 112 can also be embedded within the dielectric window 171. In some embodiments, the dielectric window 171 may have a gas inlet (e.g., in the central region) configured to provide one or more process gases into the processing chamber 170.

While the concentric planar coils 112 are schematically shown as precisely aligned in the same plane and having the same antenna diameter as an example, neither is strictly required. In some embodiments, the source coil 120 and the secondary coil 130 have different antenna diameters (i.e., the cross sectional area of the conductive material of the coil itself). In some embodiments, the concentric planar coils 112 may have a slight relative vertical displacement while still being considered planar.

The source coil 120 and the secondary coil 130 may also have other configurations. In some embodiments, one of the source coil 120 and the secondary coil 130 is implemented as a planar coil at the top of the processing chamber 170 and the other coil is implemented in a helical structure around some or all of the processing chamber 170. In such a configuration, appropriate portions of the sidewalls of the processing chamber 170 may be formed from a dielectric material to allow coupling of the helical coil to the plasma 172. In some embodiments, additional coils are included, such as an additional secondary coil, at the side of the processing chamber 170, for example.

In one embodiment, the secondary coil 130 is a planar coil at the top of the processing chamber 170 while the source coil 120 is a helical coil at the side of the processing chamber 170. In another embodiment, the source coil 120 is a planar coil at the top of the processing chamber 170 while the secondary coil 130 is a helical coil at the side of the processing chamber 170. In still another embodiment, both the source coil 120 and the secondary coil 130 are helical coils at the side of the processing chamber 170.

The configuration of the magnet 140 may also vary. In various embodiments, the magnet 140 is disposed in a ring configuration (e.g., a ring magnet or multiple ring magnets, as shown). The magnet 140 may be implemented as a single continuous magnet or as a group of magnets. In some embodiments, the magnet 140 includes multiple rings. In some embodiments, the magnet 140 is disposed outside an outer radius 116 of the concentric planar coils 112, (which may be a specific example of an outermost radius of the source coil 120 and the secondary coil 130 regardless of configuration). In other embodiments, the magnet 140 is disposed within the outer radius 116. In various embodiments, the magnet 140 is disposed in a ring configuration outside the outer radius 116.

In one embodiment, the magnet 140 is disposed in a ring configuration surrounding the dielectric window 171 (as shown). However, the position of the magnet 140 (lateral position 117 and vertical position 118) may be adjusted as desired. For example, the vertical position 118 of the magnet 140 may shifted up or down. In some cases, dielectric material may be included in appropriate portions of the sidewall of the processing chamber 170 to improve penetration of the magnetic field 146.

The lateral position 117 may also be adjusted (which for a ring configuration amounts to expansion and contraction of the ring). When the lateral position 117 is reduced to be smaller than the radius of the processing chamber 170, the vertical position 118 of the magnet 140 may be increased so that the magnet 140 is above the processing chamber 170, the source coil 120, and/or the secondary coil 130.

The plasma processing system 100 may include a controller 160 that is configured to control the source power supply 122 and the secondary power supply 132, as well as other components, such as the DC power supply 142 and/or the bias power supply 176 (when included). Specifically, the controller 160 may be configured to control the timing of the application of the source power 123, the secondary power 133, the DC power 143, and the bias power 177. For example, the controller 160 may be configured to control both continuous wave application of power as well as pulsed application of power.

Further, the controller 160 may be configured to adjust various parameters of the applied power, including frequency, amplitude, DC voltage bias, duty cycle, power, and others. In various embodiments, the controller 160 is configured to adjust the secondary frequency 134. In some embodiments, the controller 160 is configured to adjust the magnitude of the magnetic field 146 (e.g., by adjusting the voltage of the DC power 143, for example).

The controller 160 may also be configured to control one or more sensors 150 configured to measure various properties of the plasma 172 or the plasma processing system 100 and provide sensor data 156 to the controller 160. The sensors 150 are configured to obtain time-resolved sensor data 156, which is then provided to the controller 160. Based on the time-resolved sensor data 156, the controller 160 is configured to control various aspects of the plasma 172 and a plasma process, such as adjusting the secondary frequency 134 and/or the DC power 143, among others.

In various embodiments, an IV sensor 152 (e.g. a current-voltage sensor, that may include a high voltage probe) is included to measure the plasma potential and/or plasma current. In various embodiments, the IV sensor 152 is configured to provide IV measurements as the sensor data 156 so that the plasma characterization information includes ion flux information (e.g., determined by processing the sensor data 156).

In one or more embodiments, an OES sensor 154 is included to measure optical emission data from the plasma 172. In various embodiments, the OES sensor 154 is configured to provide OES measurements as the sensor data 156 so that the plasma characterization information include plasma density information (e.g., determined by processing the sensor data 156). The sensors 150 may also include other sensors, such as film characterization sensors, temperature sensors, and others, as well as additional IV sensors and/or OES sensors.

The controller 160 may be implemented as a single controller (as schematically shown) or as a control system including various controllers (such as a dedicated secondary frequency adjustment controller, a magnetic field adjustment controller, etc.) and processors (whether local and remote). The controller 160 may include a processor 162 and/or a memory 164 (i.e., a non-transitory computer-readable medium) that stores a program including instructions that, when executed by the processor 162, control the source power supply 122, the secondary power supply 132, and the DC power supply 142 (when included), as well as other components of the plasma processing system 100, such as the bias power supply 176, and the sensors 150.

For example, the memory 164 may have volatile memory (e.g., random access memory (RAM)) and non-volatile memory (e.g., flash memory). Alternatively, the program may be stored in physical memory at a remote location, such as in cloud storage. The processor 162 may be any suitable processor or group of processors, including the processor of a microcontroller, a general-purpose processor (such as a central processing unit (CPU), a microprocessor, a field-programmable gate array (FPGA), an application-specific integrated circuit (ASIC), and others.

The plasma processing apparatus 110 may be configured for any type of plasma processing, and may be configured to perform more than one type of plasma process. For example, the plasma processing apparatus 110 may be a plasma deposition apparatus or a plasma etching apparatus, as examples. In various embodiments, the plasma processing apparatus 110 is a deposition apparatus, and is a plasma-enhanced deposition apparatus in some embodiments. In one embodiment, the plasma processing apparatus 110 is configured for plasma-enhanced chemical vapor deposition (PECVD). In another embodiment, the plasma processing apparatus 110 is configured for plasma-enhanced atomic layer deposition (PEALD). In one or more embodiments, the plasma processing apparatus 110 is an etching apparatus, and is a plasma etching apparatus in some embodiments. In one embodiment, the plasma processing apparatus 110 is configured for reactive-ion etching (RIE). In one embodiment, the plasma processing apparatus 110 is configured for high-aspect ratio (HAR) etching processes. Of course, the plasma processing apparatus 110 may be configured for any type of process that uses plasma (e.g., processes that value high density plasma).

The processing chamber 170 may be any suitable type of processing chamber that is configured to contain the plasma 172. For example, the processing chamber 170 may be a vacuum chamber, and is at least a high vacuum chamber in some embodiments. The pressure within the processing chamber 170 during processing of the substrate may be controlled to be any desired pressure relative to atmospheric pressure through appropriate control of flowrates of process gases and vacuum pumps.

The substrate 175 may be any suitable substrate, such as a semiconductor substrate, dielectric substrate, or metal substrate, for example. In one embodiment, the substrate 175 is a wafer substrate. In various embodiments, the substrate 175 has a diameter greater than about 150 mm. In some embodiments, the substrate 175 has a diameter greater than about 300 mm. For example, the diameter of the substrate 175 may be about 150 mm, 200 mm, 300 mm, 450 mm, or even larger. One example of a larger substrate might be a flat panel display.

As discussed throughout this disclosure, the plasma 172 may be considered as having a hybrid discharge mode. In the examples provided, the plasma 172 is generated as an ICP plasma from a source coil and modified using a secondary coil and a magnet. However, the concept of propagating electromagnetic waves through other plasma types using lower frequency power applied to a secondary coil together with a relatively weak magnetic field may be applied to other types of baseline plasma discharge modes, including capacitively coupled plasma (CCP) sources, for example. Moreover, wave propagation of wave plasma sources, such as surface wave plasma (SWP) sources helicon plasma sources (HPSs), may also be enhanced using a secondary coil and a magnet in analogous configurations as those described herein.

FIG. 2 illustrates a schematic diagram of another example plasma processing apparatus where the magnet is disposed above the source coil and the secondary coil in accordance with embodiments of the invention. The plasma processing apparatus of FIG. 2 may be a specific implementation of other plasma processing apparatuses described herein, such as the plasma processing apparatus of FIG. 1, for example. Similarly labeled elements may be as previously described.

Referring to FIG. 2, a plasma processing apparatus 210 is configured to generate a plasma 272 in a processing chamber 270. It should be noted that here and in the following a convention has been adopted for brevity and clarity wherein elements adhering to the pattern [x10] where ‘x’ is the figure number may be related implementations of a plasma processing apparatus in various embodiments. For example, the plasma processing apparatus 210 may be similar to the plasma processing apparatus 110 except as otherwise stated. An analogous convention has also been adopted for other elements as made clear by the use of similar terms in conjunction with the aforementioned numbering system.

A substrate holder 274 is disposed in the processing chamber 270 and is configured to support a substrate 275. The plasma 272 is generated in the processing chamber using a hybrid approach that involves applying AC power (e.g., RF power) with different frequencies to two separate coils (a source coil 220 and a secondary coil 230) and generating a magnetic field 246 using a magnet 240. The plasma 272 is separated from the source coil 220 and the secondary coil 230 by a dielectric window 271.

Source power 223 is coupled to the source coil 220 at a source frequency 224 while secondary power 233 is coupled to the secondary coil 230 at a secondary frequency 234. DC power 243 may be coupled to the magnet 140 (such as when the magnet is an electromagnet or an EPM). Optionally, bias power 277 may be coupled to the substrate holder 274. The combination of the magnetic field 246 with the secondary power 233 applied to the secondary coil 230 may propagate electromagnetic waves 238 in the plasma 272.

Here again, the source coil 220 and the secondary coil 230 are arranged as concentric planar coils 212 having a common central axis 211, but may have any suitable configuration. The concentric planar coils 212 have an inner coil 214 (which here is the source coil 220) and an outer coil 215 (the secondary coil 230 in this example). In various embodiments, the identities of the inner coil 214 and the outer coil 215 are switched.

In this specific example, the magnet 240 is configured as a ring magnet disposed above the concentric planar coils 212. As before, the position of the magnet 240 (lateral position 217 and vertical position 218) may be adjusted as desired. In various embodiments, the magnet 240 is disposed within an outer radius 216 of the concentric planar coils 212. However, in other embodiments, the magnet 240 is disposed above the source coil 220 and the secondary coil 230 and outside an outermost radius of the coils (such as the outer radius 216 of the concentric planar coils 212).

FIG. 3 illustrates a schematic diagram and associated qualitative power deposition of still another example plasma processing apparatus where the secondary coil is the inner coil and the magnet is disposed above the source coil and the secondary coil in accordance with embodiments of the invention. The plasma processing apparatus of FIG. 3 may be a specific implementation of other plasma processing apparatuses described herein, such as the plasma processing apparatus of FIG. 1, for example. Similarly labeled elements may be as previously described.

Referring to FIG. 3, a plasma processing apparatus 310 is configured to generate a plasma 372 in a processing chamber 370. A substrate holder 374 is disposed in the processing chamber 370 and is configured to support a substrate 375. The plasma 372 is generated in the processing chamber using a hybrid approach that involves applying source power 323 to a source coil 320 at a source frequency, applying secondary power 333 to a secondary coil 330 at a secondary frequency (that is less than the source frequency), and generating a magnetic field using a magnet 340. The plasma 372 is separated from the source coil 320 and the secondary coil 330 by a dielectric window 371.

In this specific example, the source coil 320 and the secondary coil 330 are arranged as concentric planar coils 312 with an inner coil 314 and an outer coil 315, but with switched identities compared to previous examples. Specifically, the secondary coil 330 is the inner coil 314 and the source coil 320 is the outer coil 315 in this example (only half of the plasma processing apparatus 310 is shown for visual clarity).

The generation of the plasma 372 in the processing chamber 370 using the source coil 320, the secondary coil 330, and the magnet 340 results in a qualitative power deposition 380 that extends down toward the substrate 375. The source power 323 is applied at a source frequency greater than about 10 MHz, such as about 13.6 MHz or about 27.1 MHz, for example. The secondary power 333 is applied at a secondary frequency less than about 10 MHz, such as between about 1 MHz and about 10 MHz. The strength of the magnetic field generated in the plasma by the magnet 340 is relatively weak, such as less than about 10 G.

The darker areas of the power deposition 380 represent higher power densities with the lighter areas representing the lower power densities (e.g., with the white areas being at least an order of magnitude lower than the darkest areas). It should be noted that the plasma 372 does exist even in the white areas although, it may be desirable for the power density to be higher closer to the substrate 375 for some applications (darker areas closer to the substrate 375 may be considered advantageous).

FIG. 4 illustrates a schematic diagram and associated qualitative power deposition of a conventional ICP plasma reactor for comparison purposes.

Referring to FIG. 4, a conventional ICP reactor 490 is configured to generate a plasma 492 in a processing chamber 497 using a single conventional ICP coil 491. The plasma 492 is separated from the single conventional ICP coil 491 by a dielectric window 494. An electrostatic chuck 495 (ESC) is disposed in the processing chamber 497 and configured to support a substrate 496. In contrast to the plasma processing apparatus 310 of FIG. 3, the plasma 492 generated by applying only RF source power 493 to the single conventional ICP coil 491 at a single frequency (i.e., 13.6 MHz or 27.1 Hz) results in a conventional power deposition 499 that is concentrated at the very top of the processing chamber 497.

FIGS. 5A and 5B illustrate a qualitative comparison of power deposition of plasma processing apparatuses describe herein as the secondary frequency is varied where FIG. 5A shows power deposition with a 10 MHz secondary frequency and FIG. 5B shows power deposition with a 2 MHz secondary frequency in accordance with embodiments of the invention. The plasma processing apparatuses of FIGS. 5A and 5B may be specific implementations of other plasma processing apparatuses described herein, such as the plasma processing apparatus of FIG. 1, for example. Similarly labeled elements may be as previously described.

Referring to FIGS. 5A and 5B, a plasma processing apparatus 510 is configured to generate a plasma 572 in a processing chamber 570. A substrate holder 574 is disposed in the processing chamber 570 and is configured to support a substrate 575. The plasma 572 is separated from a source coil 520 and a secondary coil 530 by a dielectric window 571.

The plasma 572 is generated in the processing chamber using a hybrid approach that involves applying source power 523 to the source coil 520 at a source frequency, applying secondary power 533 to the secondary coil 530 at a secondary frequency (that is less than the source frequency), and generating a magnetic field using a magnet 540. Similar to the concentric planar coils 112 of FIG. 1, the source coil 520 and the secondary coil 530 are arranged as concentric planar coils 512 with the source coil 520 implemented as an inner coil 514 and the secondary coil 530 implemented as an outer coil 515.

Referring to FIG. 5A, the source power 523 is applied to the source coil 520 at a source frequency of about 27 MHz (e.g., 27.1 MHz), the secondary power 533 is applied to the secondary coil 530 at a secondary frequency of about 10 MHz, and the magnet 540 generates a magnetic field of up to about 5 G in the processing chamber 570 to generate the plasma 572 resulting in a qualitative higher frequency secondary power deposition 581. For comparison, FIG. 5B shows the same plasma processing apparatus 510 when the secondary power 533 is instead applied at a secondary frequency of about 2 MHz (all other parameters staying the same) resulting in a more extended power deposition inside chamber for the secondary frequency power 582.

Both the higher frequency secondary power deposition 581 and the lower frequency secondary power deposition 582 extend down toward the substrate 575. In this specific qualitative example, the higher secondary frequency results in somewhat less vertical extension, but somewhat higher power density in the edge region. Of course, this is but one example to highlight the impact of varying a single parameter in a specific context. The behavior of the power deposition may advantageously be tailored using both parameter values and design considerations to accommodate the specific details of a given application.

FIGS. 6A and 6B illustrate a qualitative comparison of power deposition of plasma processing apparatuses described here as the applied power is varied where FIG. 6A shows power deposition with 500 W applied source power and 1 kW applied secondary power, and FIG. 6B shows power deposition with 250 W applied source and secondary power in accordance with embodiments of the invention. The plasma processing apparatuses of FIGS. 6A and 6B may be specific implementations of other plasma processing apparatuses described herein, such as the plasma processing apparatus of FIG. 1, for example. Similarly labeled elements may be as previously described.

Referring to FIGS. 6A and 6B, a plasma processing apparatus 610 is configured to generate a plasma 672 in a processing chamber 670. A substrate holder 674 is disposed in the processing chamber 670 and is configured to support a substrate 675. The plasma 672 is separated from a source coil 620 and a secondary coil 630 by a dielectric window 671.

The plasma 672 is generated in the processing chamber using a hybrid approach that involves applying source power 623 to the source coil 620 at a source frequency, applying secondary power 633 to the secondary coil 630 at a secondary frequency (that is less than the source frequency), and generating a magnetic field using a magnet 640. Similar to the concentric planar coils 112 of FIG. 1, the source coil 620 and the secondary coil 630 are arranged as concentric planar coils 612 with the source coil 620 implemented as an inner coil 614 and the secondary coil 630 implemented as an outer coil 615.

Referring to FIG. 6A, about 500 W of the source power 623 is applied to the source coil 620, about 1 kW of the secondary power 633 is applied to the secondary coil 630, and the magnet 640 generates a magnetic field of up to about 5 G in the processing chamber 670 to generate the plasma 672 resulting in a power deposition from higher applied power 683. For comparison, FIG. 6B shows the same plasma processing apparatus 610 when about 250 W of each of the source power 623 and the secondary power 633 are instead applied to the source coil 620 and the secondary coil 630, respectively, resulting in a power deposition from lower applied power 684.

Both the power deposition from higher applied power 683 and the power deposition from lower applied power 684 extend down toward the substrate 675. In this specific qualitative example, the higher applied power results in a greater vertical extension and higher power density in the edge region. Of course, this is but one example to highlight the impact of varying a single parameter in a specific context. The behavior of the power deposition may advantageously be tailored using both parameter values and design considerations to accommodate the specific details of a given application.

FIG. 7 illustrates an example method for plasma processing of a substrate in accordance with embodiments of the invention. The method of FIG. 7 may be performed using the systems and apparatuses as described herein. For example, the method of FIG. 7 may be combined with any of the embodiments of FIGS. 1-3 and 4-6B. The method steps of FIG. 7 may be performed in any suitable order or concurrently with one another as may be apparent to a person of skill in the art.

Referring to FIG. 7, a method 700 for plasma processing of a substrate includes three paths that are performed concurrently or substantially concurrently. First, during a power application step 701, plasma is generated in a processing chamber by applying RF source power at a source frequency to a source coil (plasma generation step 702). While the plasma is being generated, a DC magnetic field is also generated in the processing chamber (magnetic field generation step 703). In a wave propagation step 704, lower frequency RF power is applied to a secondary coil at a secondary frequency that is less than the source frequency. Both the plasma and the DC magnetic field are maintained during the wave propagation step 704.

At any point during the power application step 701, plasma characterization information of the plasma may be obtained during a measurement step 705. The plasma characterization information may be a single type of information or may be multiple types of information and may be obtained by processing sensor data receive from one or more sensors during the measurement step 705.

For example, the measurement step 705 may include an IV measurement step 706 during which IV data of the plasma is measured. When the IV measurement step 706 is included, the plasma characterization information may include ion flux information. In one embodiment, the ion flux information is used to adjust the secondary frequency in order to increase or decrease the ion flux to the substrate.

Similarly, the measurement step 705 may also include measuring OES data of the plasma during an OES measurement step 707. When the OES measurement step 707 is included, the plasma characterization information may include plasma density information. In one embodiment, the plasma density information is used to adjust the secondary frequency so that the plasma density increases or decreases.

The method 700 further includes an adjustment step 708 during which the secondary frequency is adjusted according to the plasma characterization information. Of course, it may not always be desirable to adjust the secondary frequency every time plasma characterization information is obtained. That is, if monitored properties of the plasma process remain at the desired levels then no adjustment may be made for the current plasma characterization information (indicated by arrow 718). Other parameters may also be adjusted during the adjustment step 708, including the magnetic field strength, such as by varying applied DC power to an electromagnetic or EPM, for example.

During some or all of the power application step 701, the substrate may be processed using the plasma (a processing step 709). After each adjustment step 708 (or omission thereof), the method 700 may be repeated (e.g., as a cycle 719) and the power application step 701, the measurement step 705 and the adjustment step 708, and the processing step 709 may be performed. The processing step 709 may be performed every iteration of the cycle 719 or the processing step 709 may be performed only for some of the iterations (e.g., when the plasma properties are in an acceptable range. The measurement step 705 may also be used to determine a process endpoint or milestones in various embodiments.

While the inventive aspects disclosed herein are described primarily in the context of semiconductor manufacturing processes, it should also be appreciated that these inventive aspects may also apply to other plasma processing applications. In particular, aspects of this disclosure may similarly apply to flat panel display manufacturing, solar cell production, medical device fabrication, aerospace component treatment, and various surface modification applications in materials science where controlled plasma characteristics are essential for achieving desired surface properties or material transformations.

Example embodiments of the invention are summarized here. Other embodiments can also be understood from the entirety of the specification as well as the claims filed herein.

Example 1. A plasma processing apparatus including: a processing chamber including a dielectric window; a source coil disposed outside the processing chamber at the dielectric window, the source coil being configured to generate plasma in the processing chamber using RF source power coupled to the source coil at a source frequency; a secondary coil configured to receive lower frequency RF power coupled to the second coil at a secondary frequency less than the source frequency; and one or more magnets configured to generate a DC magnetic field in the plasma.

Example 2. The plasma processing apparatus of example 1, where the one or more magnets include a permanent magnet, an electromagnet, an EPM, or a combination thereof.

Example 3. The plasma processing apparatus of one of examples 1 and 2, where the source coil and the secondary coil are configured as concentric planar coils disposed in substantially the same plane and share a common central axis.

Example 4. The plasma processing apparatus of example 3, where the one or more magnets are disposed within an outer radius of the concentric planar coils.

Example 5. The plasma processing apparatus of one of examples 1 to 4, where the one or more magnets are disposed in a ring configuration outside an outermost radius of the source coil and the secondary coil.

Example 6. The plasma processing apparatus of example 5, where the one or more magnets in the ring configuration surround the dielectric window separating the source coil and the secondary coil from the plasma.

Example 7. The plasma processing apparatus of one of examples 3 to 6, where the source coil is an inner coil of the concentric planar coils, and where the secondary coil is an outer coil of the concentric planar coils.

Example 8. The plasma processing apparatus of one of examples 3 to 6, where the secondary coil is an inner coil of the concentric planar coils, and where the source coil is an outer coil of the concentric planar coils.

Example 9. The plasma processing apparatus of one of examples 1 to 8, where the source frequency is greater than about 10 MHz, where the secondary frequency is less than about 10 MHz.

Example 10. A plasma processing system including: a processing chamber including a dielectric window; a source power supply configured to generate RF source power at a source frequency; a source coil electrically coupled to the source power supply and disposed outside the processing chamber at the dielectric window, the source coil being configured to generate plasma in the processing chamber using the RF source power; a secondary power supply configured to generate lower frequency RF power at a secondary frequency less than the source frequency; a secondary coil electrically coupled to the secondary power supply and configured to receive the lower frequency RF power; and one or more magnets configured to generate a DC magnetic field in the plasma.

Example 11. The plasma processing system of example 10, where the source frequency is greater than about 10 MHz, and where the secondary frequency is less than about 10 MHz.

Example 12. The plasma processing system of example 11, where the source frequency is about 27 MHz.

Example 13. The plasma processing system of one of examples 11 and 12, where the secondary frequency is about 2 MHz.

Example 14. The plasma processing system of one of examples 10 to 13, where field strength of the DC magnetic field in the processing chamber is less than about 10 G.

Example 15. The plasma processing system of one of examples 10 to 14, further including: one or more sensors configured to measure plasma characterization information of the plasma; and a controller operationally coupled to the source power supply, the secondary power supply, and the one or more sensors, the controller including a processor and a non-transitory computer-readable medium storing a program including instructions that, when executed by the processor, perform a method for plasma processing a substrate disposed in the processing chamber by generating the plasma in the processing chamber by applying the RF source power to the source coil, generating the DC magnetic field in the processing chamber using the magnet, applying lower frequency RF power to the secondary coil, while applying the lower frequency RF power and generating the magnetic field and the plasma, obtaining plasma characterization information of the plasma and adjusting the secondary frequency according to the plasma characterization information, and processing the substrate using the plasma.

Example 16. A method for plasma processing of a substrate, the method including: generating plasma in a processing chamber by applying RF source power at a source frequency to a source coil; generating a DC magnetic field in the processing chamber; applying lower frequency RF power to a secondary coil at a secondary frequency less than the source frequency; while applying the lower frequency RF power and generating the magnetic field and the plasma, obtaining plasma characterization information of the plasma, and adjusting the secondary frequency according to the plasma characterization information; and processing the substrate using the plasma.

Example 17. The method of example 16, where obtaining the plasma characterization information includes measuring IV data of the plasma, the plasma characterization information including ion flux information; and where adjusting the secondary frequency increases or decreases ion flux to the substrate.

Example 18. The method of one of examples 16 and 17, where obtaining the plasma characterization information includes measuring OES data of the plasma, the plasma characterization information including plasma density information; and where adjusting the secondary frequency increases or decreases plasma density.

Example 19. The method of one of examples 16 to 18, where field strength of the DC magnetic field in the processing chamber is less than about 10 G.

Example 20. The method of one of examples 16 to 19, where the source frequency is greater than about 10 MHz, and where the secondary frequency is less than about 10 MHz.

While this invention has been described with reference to illustrative embodiments, this description is not intended to be construed in a limiting sense. Various modifications and combinations of the illustrative embodiments, as well as other embodiments of the invention, will be apparent to persons skilled in the art upon reference to the description. It is therefore intended that the appended claims encompass any such modifications or embodiments.

What is claimed is:

1. A plasma processing apparatus comprising:
a processing chamber comprising a dielectric window;
a source coil disposed outside the processing chamber at the dielectric window, the source coil being configured to generate plasma in the processing chamber using radio frequency (RF) source power coupled to the source coil at a source frequency;
a secondary coil configured to receive lower frequency RF power coupled to the second coil at a secondary frequency less than the source frequency; and
one or more magnets configured to generate a direct current (DC) magnetic field in the plasma.

2. The plasma processing apparatus of claim 1, wherein the one or more magnets comprise a permanent magnet, an electromagnet, an electro-permanent magnet (EPM), or a combination thereof.

3. The plasma processing apparatus of claim 1, wherein the source coil and the secondary coil are configured as concentric planar coils disposed in substantially the same plane and share a common central axis.

4. The plasma processing apparatus of claim 3, wherein the one or more magnets are disposed within an outer radius of the concentric planar coils.

5. The plasma processing apparatus of claim 3, wherein the source coil is an inner coil of the concentric planar coils, and wherein the secondary coil is an outer coil of the concentric planar coils.

6. The plasma processing apparatus of claim 3, wherein the secondary coil is an inner coil of the concentric planar coils, and wherein the source coil is an outer coil of the concentric planar coils.

7. The plasma processing apparatus of claim 1, wherein the one or more magnets are disposed in a ring configuration outside an outermost radius of the source coil and the secondary coil.

8. The plasma processing apparatus of claim 7, wherein the one or more magnets in the ring configuration surround the dielectric window separating the source coil and the secondary coil from the plasma.

9. The plasma processing apparatus of claim 1, wherein the source frequency is greater than about 10 MHz, wherein the secondary frequency is less than about 10 MHz.

10. A plasma processing system comprising:
a processing chamber comprising a dielectric window;
a source power supply configured to generate radio frequency (RF) source power at a source frequency;
a source coil electrically coupled to the source power supply and disposed outside the processing chamber at the dielectric window, the source coil being configured to generate plasma in the processing chamber using the RF source power;
a secondary power supply configured to generate lower frequency RF power at a secondary frequency less than the source frequency;
a secondary coil electrically coupled to the secondary power supply and configured to receive the lower frequency RF power; and
one or more magnets configured to generate a direct current (DC) magnetic field in the plasma.

11. The plasma processing system of claim 10, wherein the source frequency is greater than about 10 MHz, and wherein the secondary frequency is less than about 10 MHz.

12. The plasma processing system of claim 11, wherein the source frequency is about 27 MHz.

13. The plasma processing system of claim 11, wherein the secondary frequency is about 2 MHz.

14. The plasma processing system of claim 10, wherein field strength of the DC magnetic field in the processing chamber is less than about 10 G.

15. The plasma processing system of claim 10, further comprising:
one or more sensors configured to measure plasma characterization information of the plasma; and
a controller operationally coupled to the source power supply, the secondary power supply, and the one or more sensors, the controller comprising a processor and a non-transitory computer-readable medium storing a program including instructions that, when executed by the processor, perform a method for plasma processing a substrate disposed in the processing chamber by
generating the plasma in the processing chamber by applying the RF source power to the source coil,
generating the DC magnetic field in the processing chamber using the magnet,
applying lower frequency RF power to the secondary coil,
while applying the lower frequency RF power and generating the magnetic field and the plasma, obtaining plasma characterization information of the plasma and adjusting the secondary frequency according to the plasma characterization information, and
processing the substrate using the plasma.

16. A method for plasma processing of a substrate, the method comprising:
generating plasma in a processing chamber by applying radio frequency (RF) source power at a source frequency to a source coil;
generating a direct current (DC) magnetic field in the processing chamber;
applying lower frequency RF power to a secondary coil at a secondary frequency less than the source frequency;
while applying the lower frequency RF power and generating the magnetic field and the plasma,
obtaining plasma characterization information of the plasma, and
adjusting the secondary frequency according to the plasma characterization information; and
processing the substrate using the plasma.

17. The method of claim 16,
wherein obtaining the plasma characterization information comprises measuring current-voltage (IV) data of the plasma, the plasma characterization information comprising ion flux information; and
wherein adjusting the secondary frequency increases or decreases ion flux to the substrate.

18. The method of claim 16,
wherein obtaining the plasma characterization information comprises measuring optical emission spectroscopy (OES) data of the plasma, the plasma characterization information comprising plasma density information; and
wherein adjusting the secondary frequency increases or decreases plasma density.

19. The method of claim 16, wherein field strength of the DC magnetic field in the processing chamber is less than about 10 G.

20. The method of claim 16, wherein the source frequency is greater than about 10 MHz, and wherein the secondary frequency is less than about 10 MHz.
